(19) United States
(12) Patent Application Publication
(10) Pub. No.: US 2025/0275339 A1
(43) Pub. Date: Aug. 28, 2025

(54) DISPLAY DEVICE

(71) Applicant: LG Display Co., Ltd., Seoul (KR)

(72) Inventors: Insu HWANG, Seoul (KR); Yubin JEONG, Gwangju (KR)

(73) Assignee: LG Display Co., Ltd., Seoul (KR)

(21) Appl. No.: 19/011,085

(22) Filed: Jan. 6, 2025

(30) Foreign Application Priority Data
Feb. 26, 2024 (KR) 10-2024-0027612

(51) Int. Cl. H10H 29/80; H10H 29/24; H10H 29/85; H10H 29/853

(52) U.S. Cl. CPC H10H 29/842; H10H 29/24; H10H 29/8517; H10H 29/853

(57) ABSTRACT

A display device includes a first substrate on which a first sub pixel area, a second sub pixel area, and a third sub pixel area are respectively defined; a light emitting diode on the first substrate; a first refractive index layer corresponding to the first sub pixel area; a second refractive index layer corresponding to the second sub pixel area; a third refractive index layer corresponding to the third sub pixel area; and a protection layer on the first, second, and third refractive index layers, wherein at least two of the first refractive index layer, the second refractive index layer, and the third refractive index layer have different refractive indices.

### CROSS-REFERENCE TO RELATED APPLICATIONS

This application claims the priority of Korean Patent Application No. 10-2024-0027612 filed on Feb. 26, 2024, in the Korean Intellectual Property Office, the disclosure of which is incorporated herein by reference.

### BACKGROUND

### Technical Field

The present disclosure relates to a display device, and more particularly, to a display device with an excellent luminous efficiency while simultaneously improving a dark spot defect and a viewing angle.

### Discussion of the Related Art

Recently, as society enters an information era, a display field that visually expresses electrical information signals has been rapidly developed and in response to this, various display devices having excellent performance, such as thin profile, light weight, and low power consumption have been developed. Specific examples of such display devices include a liquid crystal display device (LCD), a plasma display panel device (PDP), a field emission display device (FED), an organic light emitting display device (OLED), and the like.

Among such display devices, an organic light emitting display device is a display device that includes an organic emission layer between an anode and a cathode. In the organic light emitting display device, holes and electrons injected from the anode and cathode are recombined in the emission layer to form excitons, thereby generating light with a specific wavelength by emitting the energy of the excitons formed as described above. Therefore, the organic light emitting display device uses a self-emitting element to have a fast response speed and has advantages of good contrast ratio, luminous efficiency, luminance, and viewing angle characteristics.

The luminous efficiency of the organic light emitting display device may be determined by internal efficiency and external efficiency. The internal efficiency depends on the photoelectric conversion efficiency of an organic light emitting material, and the external efficiency, which is also called a light extraction (coupling) efficiency, depends on a refractive index of each layer that configures the organic light emitting diode.

### SUMMARY

An organic light emitting display device includes an organic light emitting diode that includes an anode, an emission layer, and a cathode. Further, the organic light emitting display device is configured by laminating various components, such as a protection layer, an adhesive layer, a color filter layer, and an encapsulation substrate, on the organic light emitting diode to protect the organic light emitting diode. Therefore, light emitted from the emission layer passes through various layers that configure the organic light emitting display device to be emitted to the outside. However, layers that configure the organic light emitting display device have different refractive indices and emitted light passes through interfaces having different refractive indices to cause various optical phenomena, such as reflection, absorption, scattering, and refraction. As a result, as light emitted from the emission layer passes through various layers, there are problems in that some light is not emitted to the outside to degrade the light extraction efficiency and color change according to the viewing angle is significant.

To solve these problems, a method for placing a capping layer having a high refractive index on the cathode to compensate for light and improve the color change according to the viewing angle has been proposed. A capping layer may be characterized as being a layer formed of SiNₓ or SiOₓ, and/or having a high refractive index, such as a refractive index over 1.5 or 1.6.

However, this method causes another problem in that during a process of thermally bonding a top substrate and a bottom substrate of the organic light emitting display device, the capping layer is melted due to a high temperature heat, thereby causing pores. When pores are generated due to the melted capping layer, an interfacial adhesiveness between the capping layer and the protection layer is degraded. Further, a filler used for bonding permeates below the capping layer through a portion in which the interfacial adhesiveness is weakened so that the cathode is dented. Moreover, a dark spot defect is caused by a short between the anode and the cathode.

Accordingly, embodiments of the present disclosure are directed to a display device that substantially obviates one or more of the problems due to limitations and disadvantages of the related art.

An aspect of the present disclosure is to provide a display device with excellent luminous efficiency and viewing angle characteristic while improving the dark spot defect.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawing.

To achieve these and other aspects of the inventive concepts, as embodied and broadly described herein, a display device comprises a first substrate on which a first sub pixel area, a second sub pixel area, and a third sub pixel area are respectively defined; a light emitting diode on the first substrate; a first refractive index layer corresponding to the first sub pixel area; a second refractive index layer corresponding to the second sub pixel area; a third refractive index layer corresponding to the third sub pixel area; and a protection layer on the first, second, and third refractive index layers, wherein at least two of the first refractive index layer, the second refractive index layer, and the third refractive index layer have different refractive indices.

In another aspect, a display device comprises a first substrate; first, second, and third light emitting diodes each over the first substrate in respective sub pixel areas; a first refractive index layer over the first light emitting diode; a second refractive index layer over the second light emitting diode; a third refractive index layer over the third light emitting diode, wherein one of the first, second, and third refractive index layer is different than the other ones of first, second, and third high refractive index layer.

Other detailed matters of the example embodiments are included in the detailed description and the drawings.

According to the present disclosure, effects of providing excellent luminous efficiency and improving an efficiency and a color change according to the viewing angle are provided by light compensation by refractive index differentiated inorganic layers that are disposed to correspond to a plurality of sub pixel areas.

Further, according to the present disclosure, a display device in which a capping layer is omitted to improve an optical characteristic while improving a dark spot defect by the capping layer is provided.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view of a display device according to an example embodiment of the present disclosure;

FIG. 2 is a schematic cross-sectional view of a non-display area in a display device according to an example embodiment of the present disclosure;

FIG. 3 is a cross-sectional view taken along line I-I′ of FIG. 1;

FIG. 4 is a graph illustrating a relative efficiency of each of a red sub pixel, a green sub pixel, a blue sub pixel, and a white sub pixel according to a refractive index of an inorganic layer;

FIG. 5 is a graph illustrating a relative efficiency of a red sub pixel according to a refractive index of an inorganic layer;

FIG. 6 is a graph illustrating a relative efficiency of a green sub pixel according to a refractive index of an inorganic layer;

FIG. 7 is a graph illustrating a relative efficiency of a blue sub pixel according to a refractive index of an inorganic layer; and

FIG. 8 is a graph illustrating a relative efficiency of a white sub pixel according to a refractive index of an inorganic layer.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on”, “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

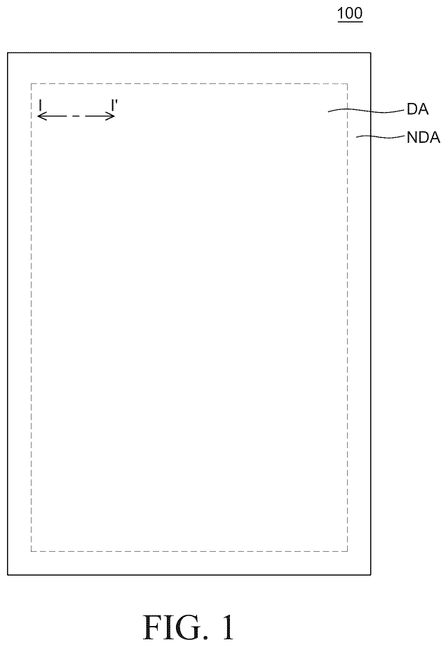

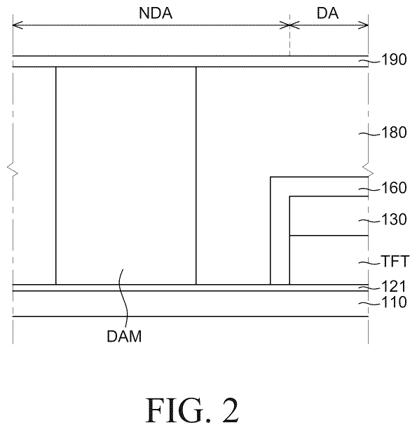

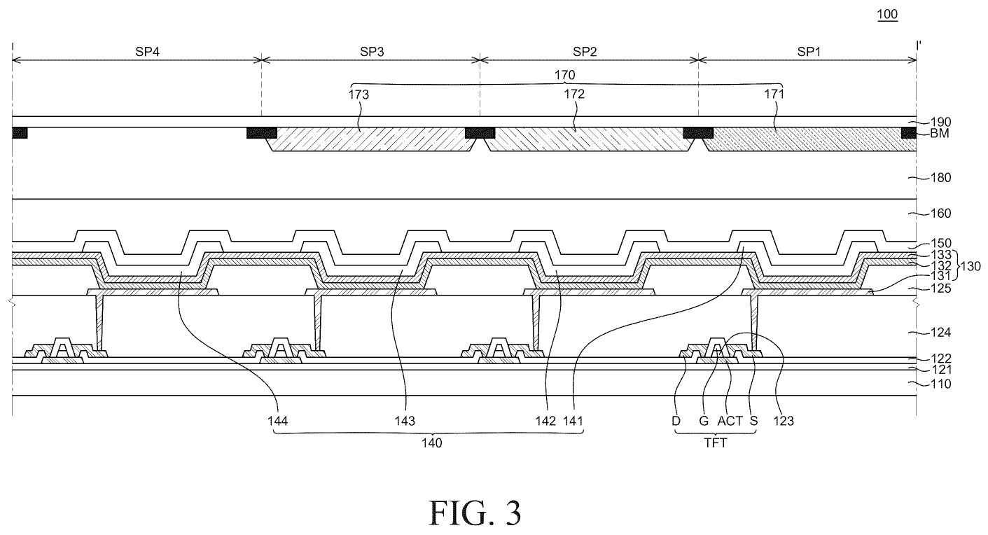

FIG. 1 is a schematic plan view of a display device according to an example embodiment of the present disclosure. FIG. 2 is a schematic cross-sectional view of a non-display area in a display device according to an example embodiment of the present disclosure. FIG. 3 is a cross-sectional view taken along line I-I′ of FIG. 1.

As shown in FIGS. 1 to 3, a display device 100 according to an example embodiment of the present disclosure includes a first substrate 110, a light emitting diode 130, a refractive index differentiated inorganic layer 140, a protection layer 150, a filler 160, an over coating layer 180, a black matrix BM, a color filter layer 170, a dam DAM (c.f., FIG. 2), and a second substrate 190. The display device 100 includes areas defined by a display area DA and a non-display area NDA. The display area DA is an area where a plurality of pixels is disposed to display images. In the display area DA, pixels including a light emitting unit for displaying images and a driving circuit for driving the pixels may be disposed. The non-display area NDA is disposed to enclose the display area DA. The non-display area NDA is an area where images are not displayed and various wiring lines, driving ICs, and printed circuit boards for driving the pixels and the driving circuits disposed in the display area DA are disposed. In the non-display area NDA, various ICs, such as a gate driver IC and a data driver IC, may be disposed.

Each of the plurality of pixels includes a plurality of sub pixels. The sub pixel is an element for displaying one color and includes an emission area in which light is emitted and a non-emission area in which light is not emitted. The plurality of sub pixels may be disposed in a matrix in the display area DA. For example, the plurality of sub pixels may be disposed in a pentile structure, but is not limited thereto. The color and the disposition of the sub pixels may vary in various forms depending on the necessity.

For example, each of the plurality of pixels may include a first sub pixel, a second sub pixel, a third sub pixel, and a fourth sub pixel. For example, the first sub pixel may be a red sub pixel, the second sub pixel may be a green sub pixel, the third sub pixel may be a blue sub pixel, and the fourth sub pixel may be a white sub pixel. However, the present disclosure is not limited thereto. If necessary, the white sub pixel may be selectively omitted.

The first substrate 110 is a base material that supports various elements configuring the display device 100. The first substrate 110 may be formed of a material having excellent insulating property and anti-moisture permeability. For example, the first substrate 110 may be a glass substrate or a plastic film, but is not limited thereto. For example, the plastic film may be a polyimide film or a polyethylene terephthalate film, but is not limited thereto.

A plurality of sub pixel areas is defined in the first substrate 110. In the first substrate 110, the first sub pixel area SP1, the second sub pixel area SP2, the third sub pixel area SP3, and the fourth sub pixel area SP4 may be defined. As described above, the first sub pixel area SP1 is a red sub pixel area, the second sub pixel area SP2 is a green sub pixel area, the third sub pixel area SP3 is a blue sub pixel area, and the fourth sub pixel area SP4 may be a white sub pixel area.

A buffer layer 121 may be disposed on the first substrate 110 to suppress permeation of oxygen or moisture. The buffer layer 121 may be formed as a single layer and may be formed with a multi-layered structure if necessary. For example, the buffer layer 121 may be formed of an inorganic material, such as silicon oxide, silicon nitride, or silicon oxynitride, but is not limited thereto. The buffer layer 121 may be omitted when there is little influence of moisture or oxygen or depending on the design structure of the display device 100.

A thin film transistor TFT is disposed on the buffer layer 121. In the drawings, among various thin film transistors that may be included in the display device 100, only a driving thin film transistor is illustrated for the sake of convenience, but a switching thin film transistor and a capacitor may also be included.

The thin film transistor TFT is an element for driving the light emitting diodes 130 disposed in the plurality of sub pixel areas SP1, SP2, SP3, and SP4. Accordingly, the thin film transistor TFT may be disposed on the buffer layer 121 to correspond to each of the plurality of sub pixel areas SP1, SP2, SP3, and SP4. The thin film transistor TFT includes a gate electrode G, an active layer ACT, a source electrode S, and a drain electrode D. For example, the active layer ACT is disposed on the buffer layer 121 and a gate insulating layer 123 may be disposed on the active layer ACT to insulate the gate electrode G. Further, an interlayer insulating layer 122 may be disposed between the gate electrode G and the source electrode S and the drain electrode D to insulate from each other. Further, the source electrode S and the drain electrode D are disposed on the interlayer insulating layer 122 to be in contact with the active layer ACT. A configuration, a structure, and a placement of the thin film transistor TFT are not limited thereto and the thin film transistor may be formed with various configurations and structures.

A planarization layer 124 for planarizing the upper surface of the thin film transistor TFT is disposed on the thin film transistor TFT. The planarization layer 124 may include a contact hole that electrically connects the thin film transistor TFT and the light emitting diode 130.

The light emitting diode 130 is disposed on the planarization layer 124. The light emitting diode 130 includes an anode 131, an emission layer 132, and a cathode 133.

The anode 131 is disposed on the planarization layer 124 to correspond to each of the plurality of sub pixel areas SP1, SP2, SP3, and SP4. For example, the anode 131 is formed to be separated for each of the plurality of sub pixel areas SP1, SP2, SP3, and SP4. The anode 131 is electrically connected to the thin film transistor TFT through a contact hole of the planarization layer 124.

For example, the anode 131 may be formed of a conductive material having a high work function to supply holes to the emission layer 132. For example, the anode 131 may include a transparent conductive material, such as indium tin oxide (ITO) and indium zinc oxide (IZO), but is not limited thereto. The anode 131 may be formed as a single layer or a multi-layered structure. When the light emitting diode 130 is implemented as a top emission type, the anode 131 may include a reflection layer that reflects light emitted from the emission layer 132 toward the cathode 133. The reflection layer may include a material having an excellent reflectivity, such as aluminum (Al), or silver (Ag), but is not limited thereto.

In FIG. 3, a bank 125 is disposed on the planarization layer 124 to expose at least a part of the anode 131. The bank 125 is disposed on the planarization layer 124 and is disposed to cover an end of the anode 131. The bank 125 divides adjacent sub pixels. Further, the bank 125 divides adjacent pixels. The bank 125 may be formed of an insulating material to insulate anodes 131 of adjacent sub pixels from each other. Further, the bank 125 may be formed of a material having a high light absorptance to suppress color mixture between adjacent sub pixels.

The emission layer 132 is disposed on the anode 131. The emission layer 132 is a layer that includes an organic light emitting material to emit light. The emission layer 132 may be formed as a single layer or a multi-layered structure. In FIG. 3, it is illustrated that the emission layer 132 is formed as one layer continued over all the plurality of sub pixel areas SP1, SP2, SP3, and SP4, but it is not limited thereto. As another example, the emission layer 132 may be formed to be separated for each of the plurality of sub pixel areas SP1, SP2, SP3, and SP4. When the emission layer 132 is formed to be separated for each of the plurality of sub pixel areas SP1, SP2, SP3, and SP4 as described above, the color filter layer 170 to be described below may be omitted.

For example, the emission layer 132 may be configured to emit white light. However, the present disclosure is not limited thereto and the emission layer 132 may be configured to emit blue light. Further, as another example, the emission layer 132 may be configured by laminating a plurality of emission layers that emits light with different colors.

The cathode 133 is disposed on the emission layer 132. The cathode 133 is not separated for each of the plurality of sub pixel areas SP1, SP2, SP3, and SP4, but is formed as one layer. The cathode 133 supplies electrons to the emission layer 132 so that the cathode may be formed of a conductive material having a low work function. For example, the cathode 133 may be formed of a transparent conductive material, such as indium tin oxide (ITO) or indium zinc oxide (IZO), or a metal, such as magnesium (Mg) or silver (Ag), and may further include a metal doping layer, but is not limited thereto.

The refractive index differentiated inorganic layer 140 may be disposed on the cathode 133. The refractive index differentiated inorganic layer 140 is disposed on the cathode 133 to refract light that may dissipate in the display device 100, among light emitted from the emission layer 132, to be emitted to the outside of the display device 100 so that the light extraction efficiency may be improved.

In the display device 100 according to the example embodiments of the present disclosure, the refractive index differentiated inorganic layer 140 includes a first high refractive inorganic layer 141 (e.g., a first refractive index layer), a second high refractive inorganic layer 142 (e.g., a second refractive index layer), a third high refractive inorganic layer 143 (e.g., a third refractive index layer), and a fourth high refractive inorganic layer 144 (e.g., a fourth refractive index layer) disposed to correspond to the plurality of sub pixel areas SP1, SP2, SP3, and SP4. For example, the first high refractive inorganic layer 141 is disposed to correspond to the first sub pixel area SP1 and the second high refractive inorganic layer 142 is disposed to correspond to the second sub pixel area SP2. The third high refractive inorganic layer 143 is disposed to correspond to the third sub pixel area SP3 and the fourth high refractive inorganic layer 144 is disposed to correspond to the fourth sub pixel area SP4.

The first high refractive inorganic layer 141, the second high refractive inorganic layer 142, the third high refractive inorganic layer 143, and the fourth high refractive inorganic layer 144 may be formed to have differentiated refractive indices according to an emitted light color of the corresponding sub pixel. Therefore, some of the first high refractive inorganic layer 141, the second high refractive inorganic layer 142, the third high refractive inorganic layer 143, and the fourth high refractive inorganic layer 144 is formed to have different refractive indices. For example, at least two of the first high refractive inorganic layer 141, the second high refractive inorganic layer 142, the third high refractive inorganic layer 143, and the fourth high refractive inorganic layer 144 have different refractive indices.

For example, a refractive index of the first high refractive inorganic layer 141 may be 1.8 or lower, a refractive index of the second high refractive inorganic layer 142 may be 1.76 or higher, a refractive index of the third high refractive inorganic layer 143 may be 1.76 or higher, and a refractive index of the fourth high refractive inorganic layer 144 may be 1.60 or higher. In this case, there are advantages in that the light extraction efficiency of the display device 100 may be improved and the luminous efficiency and the color change according to the viewing angle are improved to provide an excellent display quality.

For example, a refractive index of the first high refractive inorganic layer 141 may be 1.50 or higher and 1.80 or lower, and for example, may be 1.54 or higher and 1.70 or lower or 1.54 and higher or 1.60 or lower. Within this range, the luminous efficiency of the red sub pixel may be significantly improved, and the viewing angle characteristic may be improved.

For example, a refractive index of the second high refractive inorganic layer 142 may be 1.76 or higher and 1.95 or lower, and for example, may be 1.78 or higher and 1.95 or lower or 1.78 or higher and 1.80 or lower. Within this range, the luminous efficiency of the green sub pixel is further improved, and the viewing angle characteristic may be improved.

For example, a refractive index of the third high refractive inorganic layer 143 may be 1.78 or higher and 1.95 or lower, and for example, may be 1.79 or higher and 1.95 or lower or 1.79 or higher and 1.80 or lower. Within this range, there are advantages in that the luminous efficiency of the blue sub pixel may be maintained to be high, and an excellent viewing angle characteristic may be provided.

For example, a refractive index of the fourth high refractive inorganic layer 144 may be 1.6 or higher and 1.95 or lower, and for example, may be 1.70 or higher and 1.90 or lower or 1.75 or higher and 1.80 or lower. Within this range, the luminous efficiency of the white sub pixel may be further improved, and the viewing angle characteristic may be improved.

For example, a thickness of the refractive index differentiated inorganic layer 140 may be 800 Å to 1400 Å. Within this range, the light extraction efficiency may be significantly improved by the light compensation with the refractive index differentiated inorganic layer 140 and the color change according to the viewing angle may be minimized or at least reduced. For example, the first high refractive inorganic layer 141, the second high refractive inorganic layer 142, the third high refractive inorganic layer 143, and the fourth high refractive inorganic layer 144 may independently have thicknesses of 800 Å to 1400 Å.

For example, the refractive index differentiated inorganic layer 140 may include one or more of a silicon oxynitride film (SiON), a silicon oxide film (SiO), and a silicon nitride film (SiN). For example, the refractive index differentiated inorganic layer 140 may include a silicon oxynitride film (SiON). The silicon oxynitride film (SiON) has a high refractive index and easily adjusts the refractive index.

For example, the refractive index of the refractive index differentiated inorganic layer 140 may be adjusted by adjusting an element ratio of the silicon oxynitride film (SiON).

For example, the first high refractive inorganic layer 141 includes a silicon oxynitride film (SiON) having a content ratio of Si:O:N of 34 to 38:18 to 20:24 to 26 and the second high refractive inorganic layer 142 includes a silicon oxynitride film (SiON) having a content ratio of Si:O:N of 34 to 36:19 to 20:24 to 25. The third high refractive inorganic layer 143 includes a silicon oxynitride film (SiON) having a content ratio of Si:O:N of 36 to 38:18 to 19:25 to 26 and the fourth high refractive inorganic layer 144 may include a silicon oxynitride film (SiON) having a content ratio of Si:O:N of 36 to 38:18 to 19:25 to 26. With the aimed refractive index within this range, the light extraction efficiency for every color of each sub pixel may be significantly improved.

For example, refractive indices and content ratios of Si:O:N of the second high refractive inorganic layer 142, the third high refractive inorganic layer 143, and the fourth high refractive inorganic layer 144 are represented in Table 1, but are not limited thereto. The refractive index and the content ratio of Si:O:N of the first high refractive inorganic layer 141 are equal to or equivalent to refractive indices and content ratios of Si:O:N of the second high refractive inorganic layer 142, the third high refractive inorganic layer 143, and the fourth high refractive inorganic layer 144.

TABLE 1

| | Refractive | Content ratio (%) | | |
|---|---|---|---|---|
| Classification | index | Si | O | N |
| Second high refractive | 1.763 | 34.90 | 19.56 | 24.45 |
| inorganic layer | 1.773 | 35.90 | 19.73 | 24.39 |
| Third high refractive | 1.785 | 36.40 | 18.22 | 25.50 |
| inorganic layer | 1.796 | 37.60 | 17.95 | 25.90 |
| Fourth high refractive | 1.605 | 30.40 | 34.05 | 20.58 |
| inorganic layer | 1.608 | 30.70 | 31.93 | 22.48 |

Therefore, in the display device 100 according to the example embodiments of the present disclosure, a capping layer that is disposed on the cathode 133 to improve the light extraction efficiency may be omitted. According to the example embodiments of the present disclosure, the display device 100 includes the above-described refractive index differentiated inorganic layer 140 to significantly improve the light extraction efficiency to have excellent luminous efficiency and minimize, or at least reduce, the color change according to the viewing angle. Therefore, even though the capping layer is not provided, advantages of excellent luminance efficiency and viewing angle characteristic are provided.

As described above, when the capping layer is provided, during the process of manufacturing the display device, the capping layer is melted due to the high temperature heat to cause pores, which causes the dent of the cathode. Therefore, a short between the anode and the cathode is generated to cause a dark spot defect. According to the example embodiments of the present disclosure, the capping layer is not provided so that the advantages of excellent luminous efficiency and viewing angle characteristic may be provided while minimizing, or at least reducing, the dark spot defect.

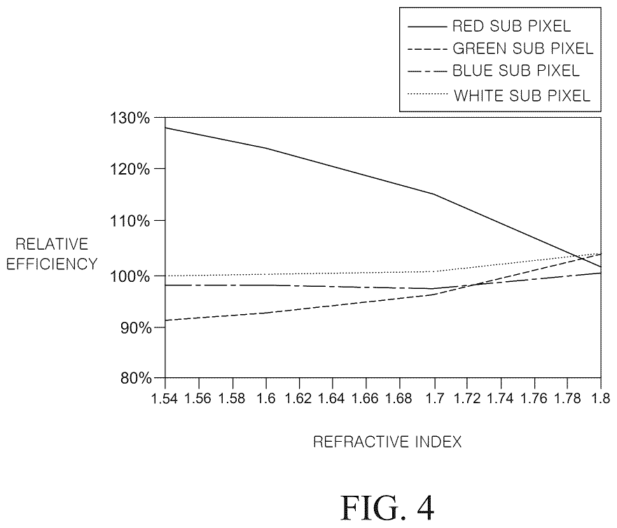

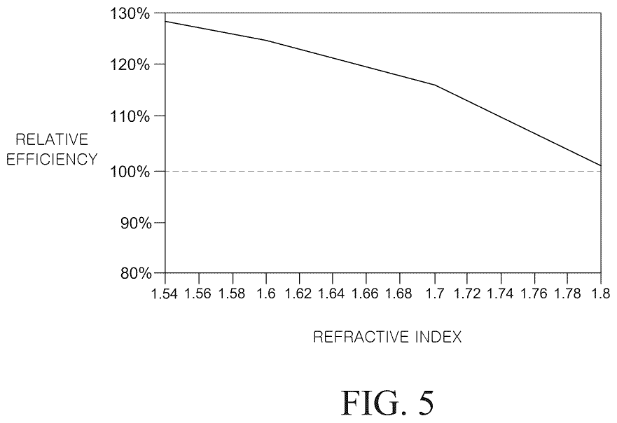

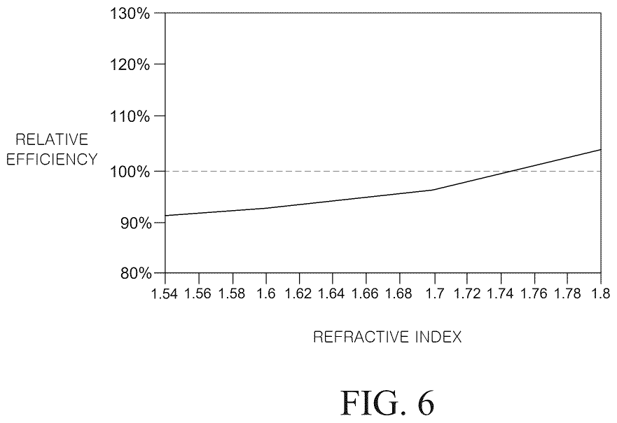

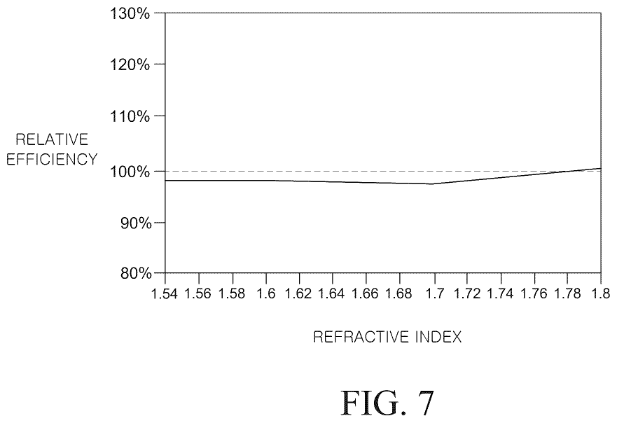

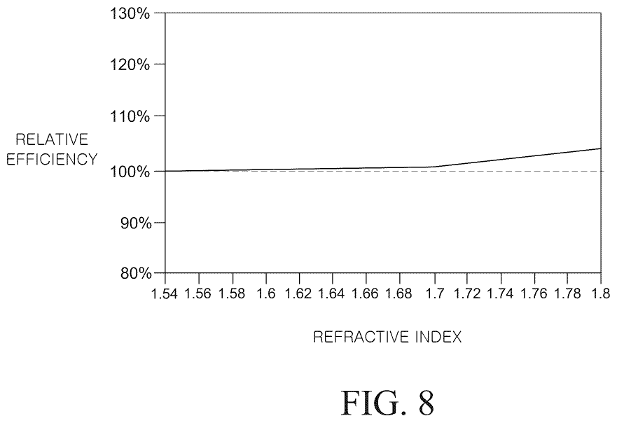

Hereinafter, the effect of the refractive index differentiated inorganic layer will be described in detail with reference to FIGS. 4 to 8. Simulation was carried out on a unit cell that included indium zinc oxide (IZO) with a thickness of 200 Å and a silicon oxynitride film (SiON) with a thickness of 1200 Å thereabove were provided as the cathode and included a red sub pixel, a green sub pixel, and a blue sub pixel and a white sub pixel. FIG. 4 is a graph illustrating a relative efficiency of each of a red sub pixel, a green sub pixel, a blue sub pixel, and a white sub pixel according to a refractive index of an inorganic layer. FIG. 5 is a graph illustrating a relative efficiency of a red sub pixel according to a refractive index of an inorganic layer. FIG. 6 is a graph illustrating a relative efficiency of a green sub pixel according to a refractive index of an inorganic layer. FIG. 7 is a graph illustrating a relative efficiency of a blue sub pixel according to a refractive index of an inorganic layer. FIG. 8 is a graph illustrating a relative efficiency of a white sub pixel according to a refractive index of an inorganic layer. The relative efficiency is based on an efficiency of a unit cell that includes a capping layer, instead of the inorganic layer.

First, with reference to FIG. 4, it is confirmed that the range of refractive index of each sub pixel in which the efficiency is improved is different. With additional reference to FIG. 5, when the refractive index of the inorganic layer is 1.8 or lower, the red sub pixel shows an efficiency that is equal to or better than the related art. In the case of the red sub pixel, it is confirmed that when the refractive index of the inorganic layer is 1.7 or lower, the efficiency is improved to approximately 115% and when the refractive index of the inorganic layer is 1.54, the efficiency is more significantly improved up to 127%. Further, with reference to FIG. 6, in the case of the green sub pixel, it is confirmed that when the refractive index is 1.76 or higher, the relative efficiency is improved to 100% or more and when the refractive index is 1.8, the efficiency is improved up to approximately 104%. Further, with reference to FIG. 7, it is confirmed that the blue sub pixel has an efficiency that is equal to the related art in the range of the refractive index that is 1.78 or higher. Further, with reference to FIG. 8, in the case of the white sub pixel, it is confirmed that when the refractive index of the inorganic layer is 1.6 or higher, the efficiency is improved to be equal to or better than the related art and when the refractive index is 1.7 or higher, an efficiency improved from the related art is provided. Further, when the refractive index is 1.8, the relative efficiency is improved to 104%.

The protection layer 150 is disposed on the refractive index differentiated inorganic layer 140. The protection layer 150 protects the light emitting diode 130 from the external environment so as not to be degraded. For example, the protection layer 150 may be an inorganic protection layer formed of an inorganic material, such as a silicon oxide film, a silicon nitride film, an aluminum nitride film, a zirconium nitride film, a titanium nitride film, a hafnium nitride film, a tantalum nitride film, an aluminum oxide film, or a titanium oxide film. As another example, the protection layer 150 may be an organic protection layer formed of an organic material, such as acrylic-based resin, epoxy-based resin, or silicon-based resin. As still another example, the protection layer 150 may be formed with a multi-layered structure including at least one inorganic protection layer and at least one organic protection layer. For example, the protection layer 150 may be formed with a multi-layered structure in which an organic protection layer is interposed between at least two inorganic protection layers, but is not limited thereto.

The second substrate 190 is disposed on the protection layer 150 to be opposite to the first substrate 110. The color filter layer 170 is formed on the second substrate 190. Therefore, the second substrate 190 may be referred to as a color filter array substrate.

The second substrate 190 may be formed of a material having excellent insulating property and anti-moisture permeability. For example, the second substrate 190 may be a glass substrate or a plastic film, but is not limited thereto. For example, the plastic film may be a polyimide film or a polyethylene terephthalate film, but is not limited thereto.

The black matrix BM and the color filter layer 170 are disposed on one surface of the second substrate 190 that is opposite to the first substrate 110. The black matrix BM and the color filter layer 170 emit light having a corresponding color to each of the plurality of sub pixels and suppress the color mixture between adjacent sub pixels. Further, the black matrix BM and the color filter layer 170 may suppress the degradation of the contrast ratio due to the external light reflection.

The black matrix BM may be disposed to correspond to the bank 125 that is a non-emission area. The black matrix BM is located on the boundary of adjacent sub pixel areas SP1, SP2, SP3, and SP4. Therefore, the black matrix BM suppresses the color mixture between adjacent sub pixels.

The color filter layer 170 includes a plurality of color filters 171, 172, and 173 corresponding to the first sub pixel area SP1, the second sub pixel area SP2, and the third sub pixel area SP3. Each of the plurality of color filters 171, 172, and 173 is configured to emit light having the same color as the corresponding sub pixel. For example, the color filter layer 170 includes a first color filter 171 corresponding to the first sub pixel area SP1, a second color filter 172 corresponding to the second sub pixel area SP2, and a third color filter 173 corresponding to the third sub pixel area SP3. Therefore, the first color filter 171 emits red light, the second color filter 172 emits green light, and the third color filter 173 emits blue light. When the emission layer 132 emits white light, a color filter is not disposed in the fourth sub pixel area SP4 that is a white sub pixel area, but the present disclosure is not limited thereto. For example, a light transmitting layer that improves a luminous efficiency and a color reproductivity may be disposed in the fourth sub pixel area SP4 that is a white sub pixel area. Further, when the emission layer 132 emits blue light, a color filter including a color conversion material that converts blue light into white light may be disposed in the fourth sub pixel area SP4 that is a white sub pixel area. And when the emission layer 132 emits green or red light, similar arrangement may be disposed.

The over coating layer 180 is disposed on the black matrix BM and the color filter layer 170. The over coating layer 180 covers one surfaces of the black matrix BM and the color filter layer 170 to provide a flat surface. The over coating layer 180 may be formed of a transparent resin, such as acrylic-based resin, so as not to degrade the optical characteristic of the display device 100, but is not limited thereto.

The dam DAM is disposed in the non-display area NDA. The dam DAM is disposed between the first substrate 110 and the second substrate 190 to enclose the display area DA. The dam DAM is disposed to enclose the filler 160 to be described below.

The dam DAM reinforces the adhesiveness between the first substrate 110 and the second substrate 170 and blocks moisture or oxygen permeating from the side surface. The dam DAM may include a sealant and a moisture absorbent. The sealant provides the adhesiveness to bond the first substrate 110 and the second substrate 170. The moisture absorbent is dispersed in the sealant to absorb moisture entering from the outside to block and delay the permeation of the moisture. When the permeation of the moisture or oxygen is sufficiently blocked according to the structure of the display device 100 or only with the sealant, the moisture absorbent may be omitted.

The filler 160 is disposed between the over coating layer 180 and the protection layer 150. The filler 160 is filled in a space between the over coating layer 180 and the protection layer 150 so as not to degrade the optical characteristic and has an adhesive characteristic to bond the first substrate 110 and the second substrate 190.

As described above, in the related art, to compensate for the light and improve the color change according to the viewing angle, a capping layer having a high refractive index is disposed on the cathode. However, in this case, during a process of applying the filler and bonding the first substrate and the second substrate with a high temperature heat, the capping layer is melted to cause pores so that the filler permeates below the capping layer to cause the dent of the cathode, which causes the dark spot defect.

According to example embodiments, the refractive index differentiated inorganic layers 141, 142, 143, and 144 are provided to correspond to the plurality of sub pixel areas SP1, SP2, SP3, and SP4, respectively. The light compensation by the refractive index differentiated inorganic layers 141, 142, 143, and 144 provides excellent luminous efficiency, improved efficiency and color change according to the viewing angle. According to example embodiments, the capping layer is omitted. As such, a layer formed of SiNₓ or SiOₓ, and/or having a high refractive index, such as a refractive index over 1.5 or 1.6, may be omitted.

Accordingly, in the display device 100 according to example embodiments of the present disclosure, there is an advantage in that during the process of applying the filler 160 and bonding the first substrate 110 and the second substrate 190 with a high temperature heat, the above-described dark spot defect is not caused. Therefore, a display device with an excellent optical characteristic is provided while improving the dark spot defect.

The example embodiments of the present disclosure can also be described as follows:

According to an aspect of the present disclosure, there is provided a display device. The display device comprises a first substrate on which a first sub pixel area, a second sub pixel area, and a third sub pixel area are respectively defined; a light emitting diode on the first substrate; a first refractive index layer corresponding to the first sub pixel area, a second refractive index layer corresponding to the second sub pixel area, and a third refractive index layer corresponding to the third sub pixel area; and a protection layer on the first, second, and third refractive index layers, wherein at least two of the first refractive index layer, the second refractive index layer, and the third refractive index layer have different refractive indices.

The first sub pixel area may be a red sub pixel area, the second sub pixel area may be a green sub pixel area, and the third sub pixel area may be a blue sub pixel area, and the first refractive index layer may have a refractive index of 1.8 or lower, the second refractive index layer may have a refractive index of 1.76 or higher, and the third refractive index layer may have a refractive index of 1.78 or higher.

The display device may further comprise a fourth refractive index layer, and the plurality of sub pixel areas may further include a fourth sub pixel area. The fourth refractive index layer may correspond to the fourth sub pixel area.

The fourth sub pixel area may be a white sub pixel area, and the fourth refractive index layer may have a refractive index of 1.60 or higher.

The first refractive index layer, the second refractive index layer, and the third refractive index layer may include a silicon oxynitride film (SiON).

The first refractive index layer may include a silicon oxynitride film (SiON) having a content ratio of Si:O:N of 34 to 38:18 to 20:24 to 26, the second refractive index layer may include a silicon oxynitride film (SiON) having a content ratio of Si:O:N of 34 to 36:19 to 20:24 to 25, the third refractive index layer may include a silicon oxynitride film (SiON) having a content ratio of Si:O:N of 36 to 38:18 to 19:25 to 26, and the fourth refractive index layer may include a silicon oxynitride film (SiON) having a content ratio of Si:O:N of 36 to 38:18 to 19:25 to 26.

A thickness of each of the first refractive index layer, the second refractive index layer, and the third refractive index layer may be 800 Å to 1400 Å.

The light emitting diode may include a plurality of anodes respectively corresponding to the first, second, and third sub pixel areas, an emission layer on the anode; and a cathode on the emission layer.

The display device may further comprise a second substrate over the protection layer; a black matrix and a color filter layer each between the second substrate and the protection layer; and an over coating layer over the protection layer and under the black matrix and the color filter layer. The color filter layer may include a first color filter corresponding to the first sub pixel area, a second color filter corresponding to the second sub pixel area, and a third color filter corresponding to the third sub pixel area.

The emission layer may be configured to emit white light.

The display device may further comprise a filler between the over coating layer and the protection layer; and a dam in a non-display area between the first substrate and the second substrate to enclose the filler. In another aspect, a display device may comprise a first substrate; first, second, and third light emitting diodes each over the first substrate in respective sub pixel areas; a first refractive index layer over the first light emitting diode; a second refractive index layer over the second light emitting diode; a third refractive index layer over the third light emitting diode, wherein one of the first, second, and third refractive index layer is different than the other ones of the first, second, and third refractive index layer.

The first, second, and third light emitting diodes may include first, second, and third anodes respectively corresponding to the first, second, and third light emitting diodes; an emission layer on the first, second, and third anodes, the emission layer being in common with the first, second, and third light emitting diodes; and a cathode on the emission layer, the cathode being in common with the first, second, and third light emitting diodes, wherein the first, second, and third refractive index layer are on the cathode respectively over the first, second, and third anodes.

The display device may further comprise a protection layer on the first, second and third refractive index layers; an over coating layer on the protection layer; a second substrate over the protection layer; and a black matrix and a color filter layer each between the second substrate and the over coating layer, wherein the color filter layer includes a first color filter over the first light emitting diode, a second color filter the second light emitting diode, and a third color filter over the third light emitting diode.

The emission layer may be configured to emit white light.

The display device may further comprise a filler between the over coating layer and the protection layer; and a dam in a non-display area between the first substrate and the second substrate to enclose the filler.

The first light emitting diode may be configured to emit red light, the second light emitting diode may be configured to emit green light, and the third light emitting diode may be configured to emit blue light. The first refractive index layer may have a refractive index of 1.8 or lower, the second refractive index layer may have a refractive index of 1.76 or higher, and the third refractive index layer may have a refractive index of 1.78 or higher.

The display device may further comprise a fourth light emitting diode over the first substrate in fourth sub pixel area that is a white sub pixel area; and a fourth refractive index layer over the fourth light emitting diode.

The fourth refractive index layer may have a refractive index of 1.60 or higher.

The first refractive index layer may include a silicon oxynitride film (SiON) having a content ratio of Si:O:N of 34 to 38:18 to 20:24 to 26, the second refractive index layer may include a silicon oxynitride film (SiON) having a content ratio of Si:O:N of 34 to 36:19 to 20:24 to 25, the third refractive index layer may include a silicon oxynitride film (SiON) having a content ratio of Si:O:N of 36 to 38:18 to 19:25 to 26, and the fourth refractive index layer may include a silicon oxynitride film (SiON) having a content ratio of Si:O:N of 36 to 38:18 to 19:25 to 26.

A thickness of each of the first, second, and third refractive index layer may be between 800 Å and 1400 Å.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a first substrate on which a first sub pixel area, a second sub pixel area, and a third sub pixel area are respectively defined;
a light emitting diode on the first substrate;
a first refractive index layer corresponding to the first sub pixel area;
a second refractive index layer corresponding to the second sub pixel area;
a third refractive index layer corresponding to the third sub pixel area; and
a protection layer on the first, second, and third refractive index layers,
wherein at least two of the first refractive index layer, the second refractive index layer, and the third refractive index layer have different refractive indices.

2. The display device according to claim 1, wherein the first sub pixel area is a red sub pixel area, the second sub pixel area is a green sub pixel area, and the third sub pixel area is a blue sub pixel area, and the first refractive index layer has a refractive index of 1.8 or lower, the second refractive index layer has a refractive index of 1.76 or higher, and the third refractive index layer has a refractive index of 1.78 or higher.

3. The display device according to claim 1, further comprising a fourth refractive index layer,
wherein the first substrate further includes a fourth sub pixel area, the fourth refractive index layer corresponding to the fourth sub pixel area.

4. The display device according to claim 3, wherein the fourth sub pixel area is a white sub pixel area and the fourth refractive index layer has a refractive index of 1.60 or higher.

5. The display device according to claim 3, wherein the first refractive index layer, the second refractive index layer, and the third refractive index layer each includes a silicon oxynitride film (SiON).

6. The display device according to claim 5, wherein the first refractive index layer includes a silicon oxynitride film (SiON) having a content ratio of Si:O:N of 34 to 38:18 to 20:24 to 26, the second refractive index layer includes a silicon oxynitride film (SiON) having a content ratio of Si:O:N of 34 to 36:19 to 20:24 to 25, the third refractive index layer includes a silicon oxynitride film (SiON) having a content ratio of Si:O:N of 36 to 38:18 to 19:25 to 26, and the fourth refractive index layer includes a silicon oxynitride film (SiON) having a content ratio of Si:O:N of 36 to 38:18 to 19:25 to 26.

7. The display device according to claim 1, wherein a thickness of each of the first refractive index layer, the second refractive index layer, and the third refractive index layer is 800 Å to 1400 Å.

8. The display device according to claim 3, wherein the light emitting diode includes:
a plurality of anodes respectively corresponding to the first, second, and third sub pixel areas;
an emission layer on the anode; and
a cathode on the emission layer.

9. The display device according to claim 1, further comprising:
a second substrate over the protection layer;
a black matrix and a color filter layer each between the second substrate and the protection layer; and
an over coating layer over the protection layer and under the black matrix and the color filter layer, and
wherein the color filter layer includes a first color filter corresponding to the first sub pixel area, a second color filter corresponding to the second sub pixel area, and a third color filter corresponding to the third sub pixel area.

10. The display device according to claim 8, wherein the emission layer is configured to emit white light.

11. The display device according to claim 9, further comprising:
a filler between the over coating layer and the protection layer; and
a dam in a non-display area between the first substrate and the second substrate to enclose the filler.

12. A display device, comprising:
a first substrate;
first, second, and third light emitting diodes each over the first substrate in respective sub pixel areas;
a first refractive index layer over the first light emitting diode;
a second refractive index layer over the second light emitting diode;
a third refractive index layer over the third light emitting diode,
wherein one of the first, second, and third refractive index layer is different than the other ones of the first, second, and third refractive index layer.

13. The display device according to claim 12, wherein the first, second, and third light emitting diodes include:
first, second, and third anodes respectively corresponding to the first, second, and third light emitting diodes;
an emission layer on the first, second, and third anodes, the emission layer being in common with the first, second, and third light emitting diodes; and
a cathode on the emission layer, the cathode being in common with the first, second, and third light emitting diodes,
wherein the first, second, and third refractive index layer are on the cathode respectively over the first, second, and third anodes.

14. The display device according to claim 13, further comprising:
a protection layer on the first, second and third refractive index layers;
an over coating layer on the protection layer;
a second substrate over the protection layer; and
a black matrix and a color filter layer each between the second substrate and the over coating layer,
wherein the color filter layer includes a first color filter over the first light emitting diode, a second color filter over the second light emitting diode, and a third color filter over the third light emitting diode.

15. The display device according to claim 14, wherein the emission layer is configured to emit white light.

16. The display device according to claim 14, further comprising:
a filler between the over coating layer and the protection layer; and
a dam in a non-display area between the first substrate and the second substrate to enclose the filler.

17. The display device according to claim 12, wherein the first light emitting diode is configured to emit red light, the second light emitting diode is configured to emit green light, and the third light emitting diode is configured to emit blue light, and
wherein the first refractive index layer has a refractive index of 1.8 or lower, the second refractive index layer has a refractive index of 1.76 or higher, and the third refractive index layer has a refractive index of 1.78 or higher.

18. The display device according to claim 12, further comprising:
a fourth light emitting diode over the first substrate in fourth sub pixel area that is a white sub pixel area; and
a fourth refractive index layer over the fourth light emitting diode.

19. The display device according to claim 18, wherein the fourth refractive index layer has a refractive index of 1.60 or higher.

20. The display device according to claim 18, wherein the first refractive index layer includes a silicon oxynitride film (SiON) having a content ratio of Si:O:N of 34 to 38:18 to 20:24 to 26, the second refractive index layer includes a silicon oxynitride film (SiON) having a content ratio of Si:O:N of 34 to 36:19 to 20:24 to 25, the third refractive index layer includes a silicon oxynitride film (SiON) having a content ratio of Si:O:N of 36 to 38:18 to 19:25 to 26, and the fourth refractive index layer includes a silicon oxynitride film (SiON) having a content ratio of Si:O:N of 36 to 38:18 to 19:25 to 26.

21. The display device according to claim 12, wherein a thickness of each of the first, second, and third refractive index layer is between 800 Å and 1400 Å.
